(19) United States
(12) Patent Application Publication
(10) Pub. No.: US 2013/0341681 A1
(43) Pub. Date: Dec. 26, 2013

(54) HETEROJUNCTION BIPOLAR TRANSISTOR WITH IMPROVED CURRENT GAIN AND A FABRICATION METHOD THEREOF

(71) Applicants: H.P. XIAO, (US); Galen HSIEH, (US)

(72) Inventors: H.P. XIAO, (US); Galen HSIEH, (US)

(21) Appl. No.: 13/530,956

(22) Filed: Jun. 22, 2012

(51) Int. Cl. H01L 29/737; H01L 21/331

(52) U.S. Cl. 257/197; 438/312; 257/E29.188; 257/E21.371

(57) ABSTRACT

A heterojunction bipolar transistor (HBT) with improved current gain and the fabrication method thereof, in which the HBT comprises a substrate, a p-type buffer layer, a sub-collector layer, a collector layer, a base layer, an emitter layer, an emitter cap layer, and an emitter contact layer. Multiple etching processes are used for etching a base electrode contact region and terminated at the base layer. A collector electrode contact region is then formed in the base electrode contact region by an etching process terminated at the sub-collector layer. A base electrode is disposed on the base layer in the base electrode contact region. A collector electrode is disposed on the sub-collector layer in the collector electrode contact region. An emitter electrode is disposed on the emitter layer.

### FIELD OF THE INVENTION

The present invention relates to a heterojunction bipolar transistor (HBT) and a fabrication method thereof, and in particular, to an HBT structure with improved current gain by having a p-type buffer layer inserted between the collector layer and the substrate layer.

### BACKGROUND OF THE INVENTION

An HBT with improved current gain properties has the advantage of high efficiency, high linearity, high power density, and small device size. It is an important device commonly used as a microwave power amplifier in wireless communications.

FIG. 1 is a schematic showing the cross-sectional view of the epitaxial layer structure for a conventional HBT. The epitaxial layers are formed on a substrate 101, comprising sequentially a sub-collector layer 107, a collector layer 109, a base layer 111, an emitter layer 113, an emitter cap layer 115, and an emitter contact layer 117.

After the epitaxial growth of the device layer structure, a base electrode 121, a collector electrode 119, and an emitter electrode 123 are fabricated. A base contact region and a collector contact region are first defined by conventional photolithography followed by etching processes. The etching process for the base contact region is terminated at the base layer 111, while the etching process for the collector contact region is terminated at the sub-collector layer 107. The base electrode 121 is disposed in the base contact region, forming an ohmic contact with the base layer 111. In the collector electrode contact region, the collector electrode 119 is disposed and forms an ohmic contact with the sub-collector layer 107. The emitter electrode 123 is formed directly on the emitter contact layer 117 and also has an ohmic contact with the emitter contact layer 117.

For the conventional HBT, high current gain properties are not easy to achieve. It is commonly believed that the device current gain properties are sensitive to the crystalline quality of the collector or the sub-collector layer. There are two main factors that would degrade the crystalline quality of the sub-collector layer. The first one is the high dislocation density in the substrate 101, which would propagate into the sub-collector thereon during epitaxial growth and hence reduce the current gain of the HBT device. The second one is the high doping level in the sub-collector layer. In order to reduce the resistive losses in the collector electrode 119, the sub-collector layer 107 is usually heavily doped (preferably with Si). However, as the doping level is increased, the defect density in the sub-collector layer 107 is also increased, leading to a degraded current gain.

To reduce the dislocation density in the sub-collector layer propagating from the substrate, a method has been disclosed in a prior art. FIG. 2 is a schematic showing the epitaxial layer structure of an HBT with improved current gain in another prior art. The main structure is basically the same as the structure shown in FIG. 1, except that a buffer layer 103 is inserted between the substrate 101 and the sub-collector layer 107. The buffer layer 103 is formed of an oxygen doped AlGaAs layer, which could suppress the dislocations penetrating from the substrate 101 into the sub-collector layer of the HBT, and hence improve the device current gain.

To avoid the degradation in the current gain caused by the heavy doping in the sub-collector layer 107, a method has been disclosed in another prior art. FIG. 3 is a schematic showing the cross-sectional view of a high current gain HBT of another prior art. The main structure is similar to the structure shown in FIG. 1, except that a δ-doped layer 105 is inserted between the substrate 101 and the sub-collector layer 107. The δ-doped layer 105 is a doping layer with a nominal thickness of only one atomic layer (also called planar doping layer). The dopant of the δ-doped layer 105 is usually Si. The defect density in the sub-collector layer 107 generated by the high doping level can be suppressed by using the δ-doped layer. The device current gain can also be improved accordingly.

In order to tackle both of the two aforementioned factors that considerably limit the device current gain, the present invention provides an improved HBT structure and a fabrication method thereof, which can suppress not only the dislocations penetrating from the substrate 101 into the sub-collector layer, but also the defect density in the sub-collector layer 107 generated by the high doping level. Therefore, a lower collector resistance and hence an HBT device with improved current gain and long-term reliability can be achieved.

### SUMMARY OF THE INVENTION

The main object of the present invention is to provide an improved HBT structure and a fabrication method thereof, in which a p-type buffer layer is inserted between the substrate and the sub-collector layer of the HBT structure. The p-type buffer layer can absorb the defects, probably the Ga vacancies, generated during the epitaxial growth of the sub-collector layer when heavily doped with Si impurities. The p-type buffer layer can also suppress the upward propagation of the dislocations from the substrate. By choosing a suitable material and dopants for the p-type buffer layer, and optimizing the doping level therein, an improved HBT with demanded device performances can be obtained. Its on-state resistance can be lowered; the efficiency of the power amplifier can be enhanced; and the current gain can be improved.

To reach the objects stated above, the present invention provides a HBT with improved current gain, which comprises sequentially from bottom to top a substrate, a p-type buffer layer, a sub-collector layer, a collector layer, a base layer and an emitter layer. At one end of the base layer, a base electrode is disposed. At one end of the sub-collector layer, a collector electrode is disposed. On the emitter layer, an emitter electrode is disposed.

Furthermore, the present invention provides a fabrication method of an HBT with improved current gain, which includes:

Forming sequentially on a substrate a p-type buffer layer, a sub-collector layer, a collector layer, a base layer, and an emitter layer;

Defining a base electrode contact region by photolithography;

Etching the base electrode contact region and terminated at the base layer by controlling the etching process;

Defining a collector electrode contact region in the base electrode contact region by photolithography;

Etching the collector electrode contact region and terminated at the collector layer by controlling the etching process;

Disposing a base electrode on the base layer and in the base electrode contact region, and forming an ohmic contact with the base layer;

Disposing a collector electrode on the sub-collector layer and in the collector electrode contact region, and forming an ohmic contact with the sub-collector layer;

Disposing an emitter electrode directly on the emitter layer and forming an ohmic contact with the emitter layer.

In implementation, an emitter cap layer can be further included between the emitter layer and the emitter electrode, such that an ohmic contact can be formed between the emitter electrode and the emitter cap layer. Furthermore, an emitter contact layer can be further included between the emitter layer and the emitter electrode, such that an ohmic contact can be formed between the emitter contact layer and the emitter electrode. An emitter cap layer can also be further included between the emitter layer and the emitter contact layer.

In implementation, the semiconductor material for the p-type buffer layer is selected from the group consisting of GaAs, AlGaAs, InGaP, InAlP, InGaAsP and AlGaInP.

In implementation, the dopant for the p-type buffer layer is selected from the group consisting of C, Zn, Mg, Be, S, Te, and the combination of the above materials.

In implementation, the preferable thickness of the p-type buffer layer is between 10 Å and 10000 Å.

For further understanding the characteristics and effects of the present invention, some preferred embodiments referred to drawings are in detail described as follows.

### BRIEF DESCRIPTION OF DRAWINGS

FIG. 1 is a schematic showing the cross-sectional view of the epitaxial layer structure for a conventional HBT.

FIG. 2 is a schematic showing the cross-sectional view of the epitaxial layer structure of an HBT with improved current gain in another prior art.

FIG. 3 is a schematic showing the cross-sectional view of a high current gain HBT in another prior art.

FIG. 4˜7 are schematics showing the cross-sectional views of the improved epitaxial layer structure of an HBT according to the various embodiments provided by the present invention.

FIG. 8 is a flow chart of an embodiment of the fabrication method of an HBT with an improved epitaxial layer structure provided by the present invention.

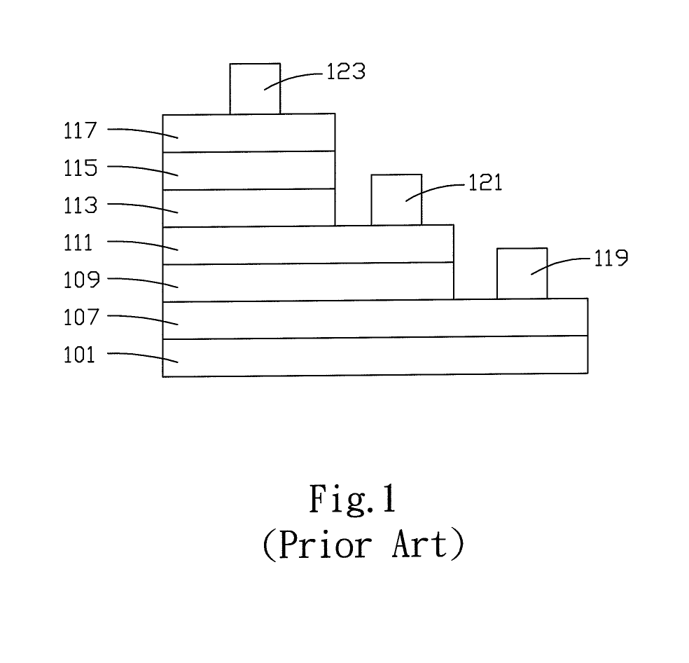

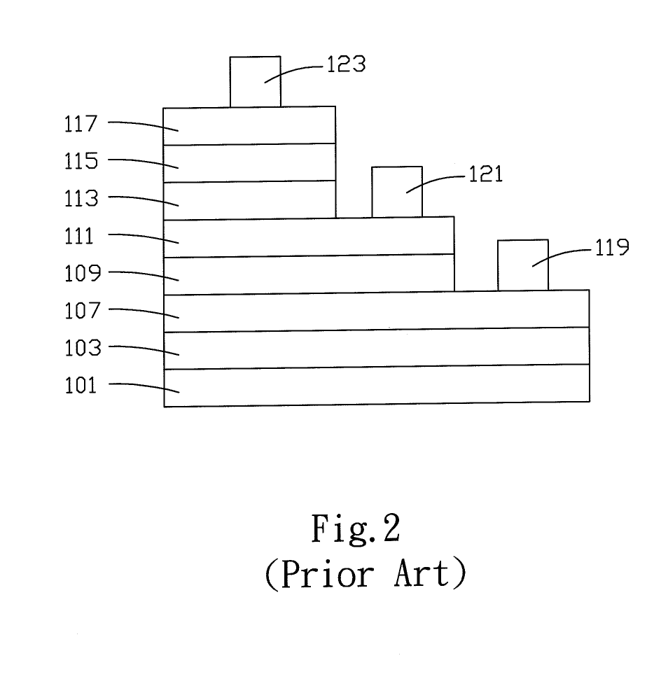

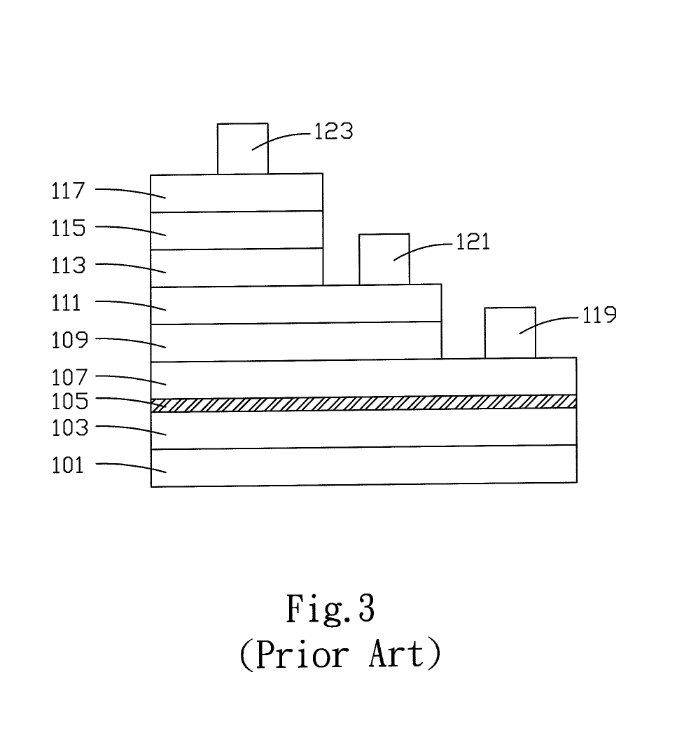

### DETAILED DESCRIPTIONS OF PREFERRED EMBODIMENTS

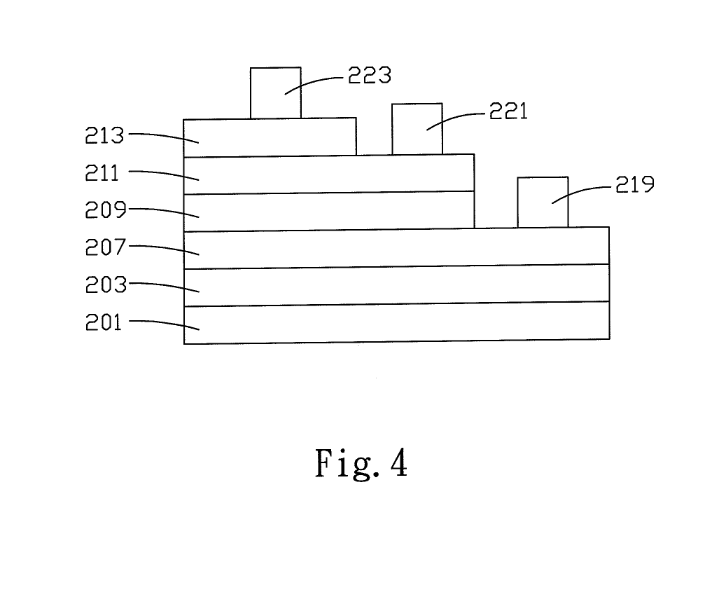

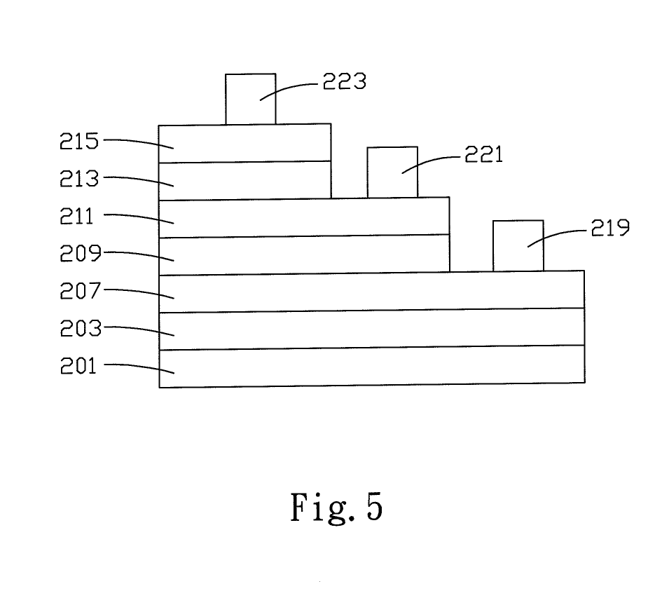

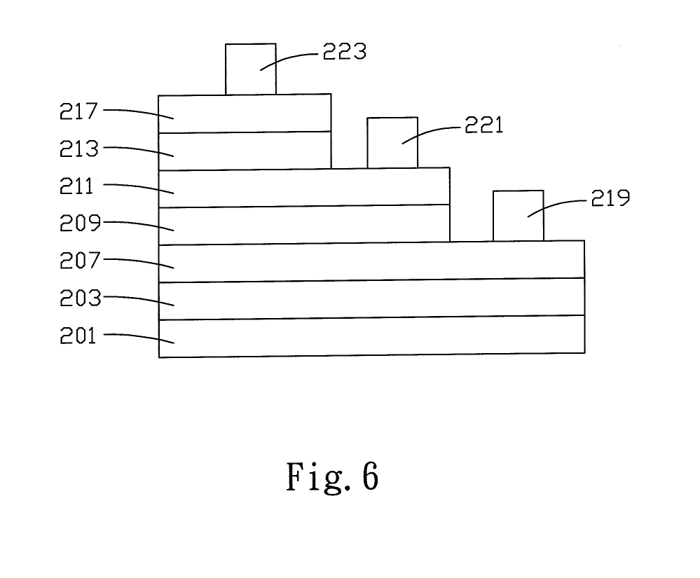

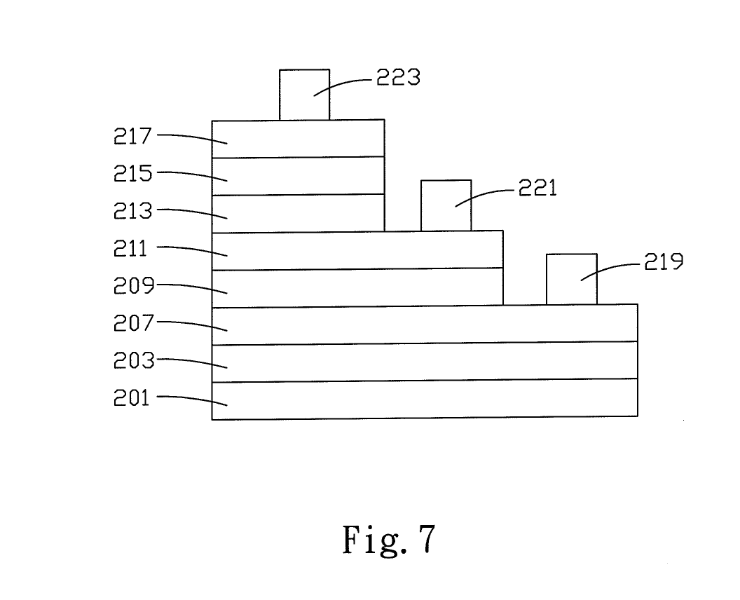

FIG. 4 is a schematic showing the improved epitaxial layer structure of an HBT provided by the present invention. The structure comprises sequentially a substrate 201, a p-type buffer layer 203, a sub-collector layer 207, a collector layer 209, a base layer 211, an emitter layer 213, a collector electrode 219, a base electrode 221, and an emitter electrode 223.

In the structure provided by the present invention, the substrate 201 is preferably a semi-insulating GaAs substrate. The p-type buffer layer 203 is formed on the substrate 201 by conventional epitaxial growth techniques, such as molecular beam epitaxy (MBE) or metalorganic chemical vapor deposition (MOCVD). The material for the p-doped buffer layer is preferably selected from the group consisting of GaAs, AlGaAs, InGaP, InAlP, InGaAsP and AlGaInP. The dopant of the p-type buffer layer is preferably a material selected from the group consisting of C, Zn, Mg, Be, S, Te, and the combination of the above materials. The preferable thickness of the p-type buffer layer is between 10 Å and 10000 Å. After the formation of the p-type buffer layer 203, the sub-collector layer 207 is then grown thereon. The sub-collector layer 207 is usually a layer of n-type GaAs heavily doped with Si. The collector layer 209 is then grown on the sub-collector layer 207. The collector layer 209 is usually a layer of n-type GaAs also doped with Si. The base layer 211 is then grown on the collector layer 209. The base layer 211 is usually a layer of p-type doped GaAs, and doped preferably with carbon or some other p-type dopants. The epitaxial layer structure is finally completed by growing an emitter layer 213 on the base layer 211. The emitter layer 213 is made preferably of Si-doped n-type InGaP.

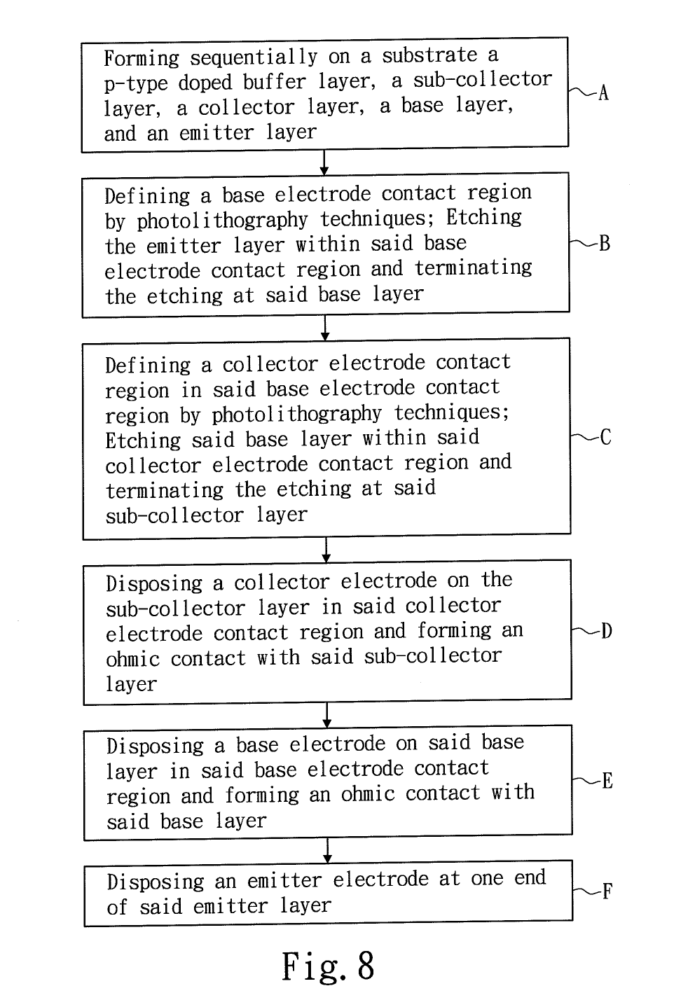

FIG. 8 is a flow chart of an embodiment of the fabrication method of an HBT with an improved epitaxial layer structure provided by the present invention. As shown in step A, the layer structure of the device is first formed by epitaxial growth techniques. Then, as shown in step B˜F, the base electrode, collector electrode, and the emitter electrode are disposed. A base electrode contact region is first defined by conventional photolithography. The emitter layer 213 within the base electrode contact region is then removed by either dry etching or wet chemical etching processes. The etching processes can be terminated at the base layer 211 by controlling the etching time during the dry etching process, or using a suitable etching solution to achieve selective etching between the emitter and the base materials. After the formation of the base electrode contact region, a collector electrode contact region is then defined by photolithography in the base electrode contact region. The base layer 211 and the collector layer 209 within the collector electrode contact region are etched, and the etching is terminated at the sub-collector layer 207 by controlling the etching processes. In the base electrode contact region, a base electrode 221 is disposed on the base layer 211, forming an ohmic contact. A collector electrode 219 is disposed in the collector electrode contact region, forming an ohmic contact with the sub-collector layer 207. Finally, an emitter electrode 223 is fabricated by directly forming an ohmic contact on the emitter layer 213.

FIG. 5 is a schematic showing the device layer structure of another embodiment of the present invention. The structure is basically the same as the embodiment shown in FIG. 4, except that an emitter cap layer 215 is inserted between the emitter layer 213 and the emitter electrode 223. The emitter cap layer 215 is made preferably of Si-doped n-type GaAs. It can also be an n-type AlGaAs layer, or an n-type multilayer formed by the combinations of GaAs and AlGaAs layers. Due to the presence of the emitter cap layer 215, an additional etching process is required for the fabrication of the base electrode contact region (step B of FIG. 8). The emitter cap layer 215 within the base electrode contact region has to be etched first, and then followed the etching process for the emitter layer 213. In addition, the emitter electrode 223 is disposed directly on the emitter cap layer 215 and forms an ohmic contact.

FIG. 6 is a schematic showing the device layer structure of another embodiment of the present invention. The main structure is basically the same as the embodiment shown in FIG. 4, except that an emitter contact layer 217 is inserted between the emitter layer 213 and the emitter electrode 223. The emitter contact layer 217 is preferably a n-type InGaAs layer, and the preferable dopant is Te, Si or similar materials. During the fabrication of the base electrode contact region (step B of FIG. 8), an additional etching process is required for the emitter contact layer 217 prior to the etching process for the emitter layer 213. In this structure, the emitter electrode 223 forms an ohmic contact with the emitter contact layer 217.

FIG. 7 is a schematic showing the device layer structure of another embodiment of the present invention. The main structure is the same as the embodiment shown in FIG. 6, except that an emitter cap layer 215 is inserted between the emitter layer 213 and the emitter contact layer 217. The emitter cap layer 215 is made preferably of Si-doped n-type GaAs. It can also be an n-type AlGaAs layer, or an n-type multilayer formed by the combinations of GaAs and AlGaAs layers. Between the etching processes for the emitter contact layer 217 and the emitter layer 213, an additional etching process for the emitter cap layer 215 is necessary for the fabrication of the base electrode contact region.

To sum up, the present invention can indeed get its anticipated object by incorporating a p-type buffer layer to improve the current gain of an HBT. The on-state resistance of the device can be significantly decreased, while the current gain and the efficiency of the power amplifier can be enhanced remarkably. The present invention also provides fabrication processes for HBTs with improved device reliability.

The description referred to the drawings stated above is only for the preferred embodiments of the present invention. Many equivalent local variations and modifications can still be made by those skilled at the field related with the present invention and do not depart from the spirits of the present invention, so they should be regarded to fall into the scope defined by the appended claims.

1. A heterojunction bipolar transistor (HBT) with improved current gain, comprising:
a substrate;
a p-type buffer layer, formed on said substrate;
a sub-collector layer, formed on said p-type buffer layer;
a collector layer, formed on said sub-collector layer;
a base layer, formed on said collector layer;
an emitter layer, formed on said base layer;
a collector electrode, disposed at one end of said sub-collector layer;
a base electrode, disposed at one end of said base layer; and
an emitter electrode, disposed on said emitter layer.

2. The HBT with improved current gain according to claim 1, wherein said p-type buffer layer is formed of the material selected from the group consisting of GaAs, AlGaAs, InGaP, InAlP, InGaAsP and AlGaInP.

3. The HBT with improved current gain according to claim 1, wherein the dopant of said p-type buffer layer is selected from the group consisting of C, Zn, Mg, Be, S, Te, and the combination of the above materials.

4. The HBT with improved current gain according to claim 1, wherein the thickness of said p-type buffer layer is between 10 Å and 10000 Å.

5. The HBT with improved current gain according to claim 1, wherein an emitter cap layer is further included between said emitter layer and said emitter electrode.

6. The HBT with improved current gain according to claim 5, wherein an emitter contact layer is further included between said emitter cap layer and said emitter electrode.

7. The HBT with improved current gain according to claim 1, wherein an emitter contact layer is further included between said emitter layer and said emitter electrode.

8. A fabrication method for an HBT with improved current gain, comprising the following steps:
forming sequentially on a substrate a p-type buffer layer, a sub-collector layer, a collector layer, a base layer, and an emitter layer;
defining a base electrode contact region by photolithography techniques;
etching the emitter layer within said base electrode contact region and terminating the etching at said base layer;
defining a collector electrode contact region in said base electrode contact region by photolithography techniques;
etching said base layer within said collector electrode contact region and terminating the etching at said sub-collector layer;
disposing a collector electrode on the sub-collector layer in said collector electrode contact region and forming an ohmic contact with said sub-collector layer;
disposing a base electrode on said base layer in said base electrode contact region and forming an ohmic contact with said base layer; and
disposing an emitter electrode at one end of said emitter layer.

9. The fabrication method according to claim 8, wherein said p-type buffer layer is formed of the material selected from the group consisting of GaAs, AlGaAs, InGaP, InAlP, InGaAsP and AlGaInP.

10. The fabrication method according to claim 8, wherein the dopant of said p-type buffer layer is selected from the group consisting of C, Zn, Mg, Be, S, Te, and the combination of the above materials.

11. The fabrication method according to claim 8, wherein the thickness of said p-type buffer layer is between 10 Å and 10000 Å.

12. The fabrication method according to claim 8, wherein said emitter electrode forms an ohmic contact with said emitter layer.

13. The fabrication method according to claim 8, wherein an emitter cap layer is further included between said emitter layer and said emitter electrode.

14. The fabrication method according to claim 13, wherein said emitter electrode forms an ohmic contact with said emitter cap layer.

15. The fabrication method according to claim 13, wherein an emitter contact layer is further included between said emitter cap layer and said emitter electrode, and said emitter electrode forms an ohmic contact with said emitter contact layer.

16. The fabrication method according to claim 8, wherein an emitter contact layer is further included between said emitter layer and said emitter electrode, and said emitter electrode forms an ohmic contact with said emitter contact layer.
